(19) United States
(12) Patent Application Publication
(10) Pub. No.: US 2025/0337438 A1
(43) Pub. Date: Oct. 30, 2025

(54) METHOD AND DEVICE FOR DECODING ERROR CORRECTING CODE

(71) Applicants: POSTECH RESEARCH AND BUSINESS DEVELOPMENT FOUNDATION, Pohang-si (KR); Seoul National University R&DB Foundation, Seoul (KR); Research & Business Foundation SUNGKYUNKWAN UNIVERSITY, Suwon-si (KR); University of Ulsan Foundation For Industry Cooperation, Ulsan (KR)

(72) Inventors: Yongjune KIM, Pohang-si (KR); Seong-Joon PARK, Seoul (KR); Sang-Hyo KIM, Seoul (KR); Hee-Youl KWAK, Ulsan (KR); Jong Seon NO, Seoul (KR)

(73) Assignees: POSTECH RESEARCH AND BUSINESS DEVELOPMENT FOUNDATION, Pohang-si (KR); Seoul National University R&DB Foundation, Seoul (KR); Research & Business Foundation SUNGKYUNKWAN UNIVERSITY, Suwon-si (KR); University of Ulsan Foundation For Industry Cooperation, Ulsan (KR)

(21) Appl. No.: 19/090,293

(22) Filed: Mar. 25, 2025

(30) Foreign Application Priority Data
Apr. 30, 2024 (KR) 10-2024-0058095

(51) Int. Cl. H03M 13/11

(52) U.S. Cl. CPC H03M 13/1111; H03M 13/1148

(57) ABSTRACT

A method and device for decoding error correcting code (ECC) are provided. The method includes obtaining a received word generated based on a transmitted code word, obtaining a reliability vector of the received word and a syndrome vector of the received word, updating at least one of the reliability vector of the received word and the syndrome vector of the received word at least once based on a plurality of cross-attentions based on the reliability vector and the syndrome vector, and outputting an estimate of the transmitted code word based on a result of the update.

### CROSS-REFERENCE TO RELATED APPLICATION

This application claims the benefit of Korean Patent Application No. 10-2024-0058095 filed on Apr. 30, 2024, in the Korean Intellectual Property Office, the entire disclosure of which is incorporated herein by reference for all purposes.

### BACKGROUND

### 1. Field of the Invention

The following embodiments relate to a method and device for decoding error correcting code.

### 2. Description of the Related Art

In a recent digital communication system, data may be transmitted through electronic, optical, or wireless means. In the data transmission process, the data may be corrupted due to various causes and without effectively processing the causes, the reliability of the data and communication quality may be degraded. Accordingly, a method of detecting and correcting an error in transmitted data is one of the core elements of the communication system design.

Error correcting code (ECC) may be code designed to detect and correct an error that may occur during data transmission and may have various types, such as hamming code, Bose-Chaudhuri-Hocquenghem (BCH) code, polar code, and low-density parity-check (LDPC) code. The method of correcting and modulating an error in a digital communication system may be an essential element to ensure accurate and efficient transmission of data and may require continuous technical development.

### SUMMARY

According to an embodiment, a method of decoding error correcting code (ECC) includes obtaining a received word generated based on a transmitted code word, obtaining a reliability vector of the received word and a syndrome vector of the received word, updating at least one of the reliability vector of the received word and the syndrome vector of the received word at least once based on a plurality of cross-attentions based on the reliability vector and the syndrome vector, and outputting an estimate of the transmitted code word based on a result of the update.

At least one of the plurality of cross-attentions includes a masked cross-attention, and the masked cross-attention updates at least one of the reliability vector and the syndrome vector using a mask matrix.

The mask matrix includes a parity check matrix indicating a relationship between an element of the received word and a parity check constraint, and the parity check matrix and a transpose matrix of the parity check matrix are used for a cross-reference update between the reliability vector and the syndrome vector.

The cross-attention includes a first cross-attention configured to update the reliability vector of the received word and a second cross-attention configured to update the syndrome vector of the received word.

The updating at least once includes updating the reliability vector of the received word by projecting the reliability vector of the received word to a query and projecting the syndrome vector of the received word to a key and a value.

The updating of the reliability vector of the received word includes using a first mask matrix based on the parity check matrix.

The updating at least once includes updating the syndrome vector of the received word by projecting the syndrome vector of the received word to a query and projecting the reliability vector of the received word to a key and a value.

The updating of the syndrome vector of the received word includes using a second mask matrix based on the parity check matrix.

The updating at least once includes, when the update of the reliability vector of the received word in the first cross-attention is performed prior to the update of the syndrome vector of the received word in the second cross-attention, projecting an updated reliability vector of the received word in the first cross-attention to a key and a value and using the updated reliability vector as an input of the second cross-attention.

The updating at least once includes, when the update of the syndrome vector of the received word in the second cross-attention is performed prior to the update of the reliability vector of the received word in the first cross-attention, projecting an updated syndrome vector of the received word in the second cross-attention to a key and a value and using the updated syndrome vector as an input of the first cross-attention.

The received word is converted by applying binary phase shift keying (BPSK) and additive white Gaussian noise (AWGN) to the transmitted code word.

According to an embodiment, an electronic device includes a memory configured to store instructions, and one or more processors, wherein the instructions, when performed by the one or more processors, cause the electronic device to obtain a received word generated based on a transmitted code word, obtain a reliability vector of the received word and a syndrome vector of the received word, update at least one of the reliability vector of the received word and the syndrome vector of the received word at least once based on a plurality of cross-attentions based on the reliability vector and the syndrome vector, and output an estimate of the transmitted code word based on a result of the update.

At least one of the plurality of cross-attentions includes a masked cross-attention, and the masked cross-attention updates at least one of the reliability vector and the syndrome vector using a mask matrix.

The mask matrix includes a parity check matrix indicating a relationship between an element of the received word and a parity check constraint, and the parity check matrix and a transpose matrix of the parity check matrix are used for cross-reference update between the reliability vector and the syndrome vector.

The cross-attention includes a first cross-attention configured to update the reliability vector of the received word and a second cross-attention configured to update the syndrome vector of the received word.

The instructions, when performed by the one or more processors, cause the electronic device to update the reliability vector of the received word by projecting the reliability vector of the received word to a query and projecting the syndrome vector of the received word to a key and a value.

The instructions, when performed by the one or more processors, cause the electronic device to update the syndrome vector of the received word by projecting the syndrome vector of the received word to a query and projecting the reliability vector of the received word to a key and a value.

According to an embodiment, an ECC decoder includes an embedding layer configured to obtain a reliability vector of a received word generated based on a transmitted code word and a syndrome vector of the received word, a decoder layer configured to update at least one of the reliability vector of the received word and the syndrome vector of the received word at least once and including a plurality of cross-attentions, and an output layer configured to output an estimate of the transmitted code word based on a result of the update.

At least one of the plurality of cross-attentions includes a masked cross-attention, and the masked cross-attention updates at least one of the reliability vector and the syndrome vector using a mask matrix.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a flowchart illustrating operations of an error correcting code (ECC) decoder according to an embodiment;

FIGS. 2 and 3 are diagrams schematically illustrating operations of an ECC decoder including a cross-attention message-passing transformer (CrossMPT) according to an embodiment;

FIG. 4 schematically illustrates a digital communication system applied with CrossMPT according to an embodiment;

FIG. 5 is a schematic diagram illustrating a parity check matrix according to an embodiment;

FIG. 6 schematically illustrates a conceptual example of a message-passing algorithm according to an embodiment; and

FIG. 7 is a diagram illustrating a block diagram of an electronic device according to an embodiment.

### DETAILED DESCRIPTION

The following detailed structural or functional description is provided as an example only and various alterations and modifications may be made to the examples. Here, the examples are not construed as limited to the disclosure and should be understood to include all changes, equivalents, and replacements within the idea and the technical scope of the disclosure.

Terms, such as first, second, and the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

It should be noted that if one component is described as being “connected”, “coupled”, or “joined” to another component, a third component may be “connected”, “coupled”, and “joined” between the first and second components, although the first component may be directly connected, coupled, or joined to the second component.

The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof.

Unless otherwise defined, all terms, including technical and scientific terms, used herein have the same meaning as commonly understood by one of ordinary skill in the art to which this disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. When describing the embodiments with reference to the accompanying drawings, like reference numerals refer to like elements and a repeated description related thereto will be omitted.

One purpose of a digital communication system may be to stably transmit information when transmitting the information from a source to a destination through a noisy channel. Accordingly, error correcting code (ECC) may be important to ensure the integrity of data transmitted from the digital communication system.

A conventional model-free neural network decoder may use an arbitrary neural network architecture as an ECC decoder without depending on prior knowledge of a specific decoding algorithm. The neural network decoder may include a preprocessing step in which the reliability and a syndrome value of a received word as inputs to avoid an overfitting problem. This preprocessing may allow the neural network decoder to effectively learn channel noise by resolving overfitting. A transformer-based decoder (an ECC transformer) may be implemented to concatenate the reliability and a syndrome value of a received word to a single input vector and learn the multiplicative noise of a channel. In this case, a transformer structure may be used for learning and more particularly, a self-attention block may be used. In a self-attention block, a mask matrix derived from a parity check matrix (PCM) may provide information on a relationship of all locations of an input vector for ease of the learning process of the neural network decoder.

The ECC decoder described below may separate a reliability vector from a syndrome vector by recognizing distinguished information characteristics of the reliability vector and the syndrome vector of a received word. A binary syndrome vector may transmit information of a bit (or element) error location, whereas a real-valued reliability vector may indicate the reliability of each bit location. The ECC decoder may include a new transformer-based decoding architecture that is specifically designed to effectively process the separated reliability syndrome vector and syndrome vector through intentional separation.

The ECC decoder may include a cross-attention message-passing transformer (CrossMPT) as a new element for ECC decoding.

The CrossMPT may effectively utilize different information characteristics by separately processing the reliability vector and the syndrome vector without concatenating the reliability vector and the syndrome vector. A masked cross-attention block may be used to iteratively update the reliability vector and the syndrome vector. The CrossMPT may use a PCM H and its transpose matrix H^{T} as a mask matrix to help training. This method may be supported by the inherent representation of the PCM for a “reliability-syndrome” relationship and may coincide with the purpose of the transformer decoding architecture. The CrossMPT may be an architecture in which an iterative message-passing framework is integrated with a cross attention-based transformer architecture.

Hereinafter, the ECC decoder implemented as a CrossMPT is described.

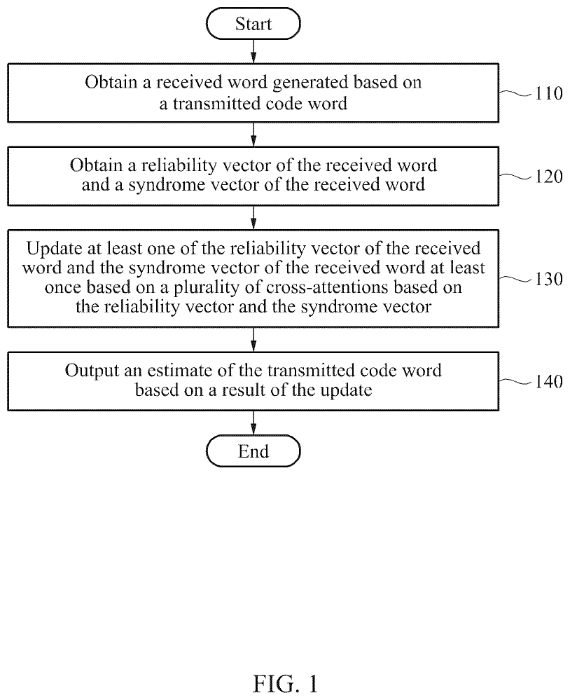

FIG. 1 is a flowchart illustrating operations of an error correcting code (ECC) decoder according to an embodiment.

Although operations of FIG. 1 may be performed in the illustrated order and manner therein, the order of some of the operations may change or some of the operations may be omitted, without departing from the spirit and scope of the illustrated example. The operations illustrated in FIG. 1 may be performed in parallel or simultaneously.

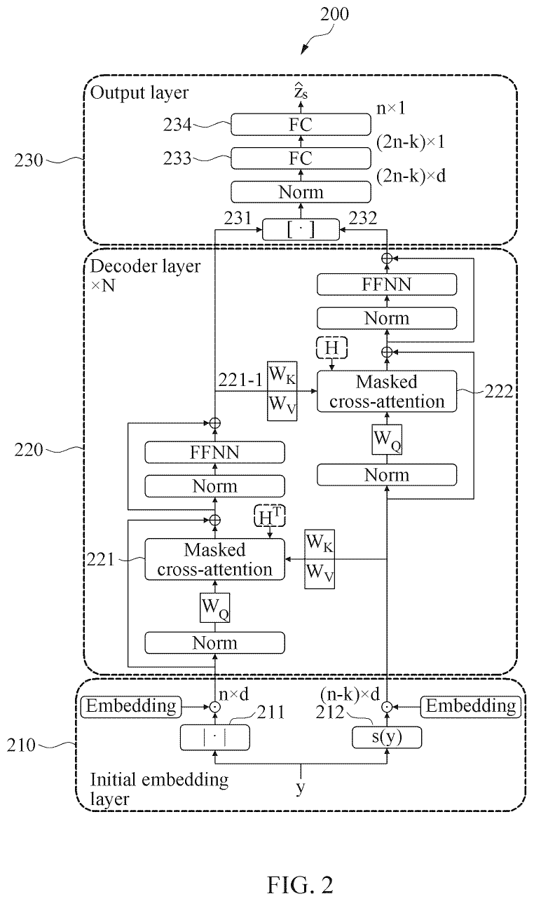

For ease of description, the operations of FIG. 1 may be described with reference to an ECC decoder 200 of FIG. 2. The ECC decoder 200 may be an ECC message-passing decoder using a cross attention-based transformer.

The ECC decoder 200 may be an electronic device for estimating an original code word from a received word through a CrossMPT. The ECC decoder 200 may estimate an original code word by operations of an initial embedding layer 210, a decoder layer 220, and an output layer 230.

In operation 110, the ECC decoder 200 may obtain a received word generated based on a transmitted code word. The received word may be a result of the transmitted code word, which is transformed as noise is added thereto by a communication channel when the transmitted code word, which is the original code word, is transmitted. The noise may include a random signal distortion element, such as additive white Gaussian noise (AWGN), and may be used as input data for reconstructing the original code word through a decoding process by a receiver side. The received word may be a converted message as binary phase shift keying (BPSK) or AWGN is applied to the transmitted code word. The BPSK may be one of digital modulation techniques used in a communication system.

The BPSK may be modulation that projects (or encode) each data bit (typically represented as 0 or 1) to a single phase change. The BPSK may be modulation that changes a phase of a carrier wave, which is a sine wave, according to binary data. The BPSK may represent a binary value using two phases. For example, 0 may be represented as a phase signal cos(ωt+0)=cos(ωt) at 0 degree and 1 may be represented as a phase signal cos(ωt+π)=−cos(ωt) at 180 degrees. In this case, baseband signal values of two signals may be 1 and −1, respectively. A signal generated as a result may be transmitted through a communication channel and in a receiver, a phase of the received signal may be detected and the phase may be converted into the binary data.

The AWGN may be one of noise types frequently occurring in the communication system. The AWGN may follow a Gaussian probability density function and may have a constant power in all frequencies. The AWGN may be a cause of distortion of an original signal when the signal reaches the receiver as the AWGN is added to the signal.

In the digital communication system, the transmitted code word may be a transmitted original code word x. The transmitted code word x may become xₛ by passing through phase shift modulation and may become a received word y=xₛ+z=xₛ×\tilde{z}ₛ) as the AWGN is added thereto. In this case, Zs may be multiplicative noise. The multiplicative noise may occur while demodulating or processing a signal in the communication system. The multiplicative noise may occur mainly because of a change in an amplitude of a signal while transmitting, receiving, or processing the signal. Due to a loss or a gain occurring while the signal passes through a medium, noise that is multiplied by the original signal may occur.

In operation 120, the ECC decoder 200 may obtain a reliability vector (e.g., an absolute value vector 211) of the received word and a syndrome vector 212 of the received word.

The reliability vector may be a vector indicating the reliability of each bit (or element) or symbol of the received data through the communication channel and may be represented as an absolute vector. The reliability vector may be an indicator of the accuracy of data and may indicate that when the reliability is high, the possibility that a corresponding bit (or element) is correctly transmitted is high. However, the reliability vector is not limited to an absolute value and may be used as a real vector itself.

In the provided embodiment, the reliability vector is mainly represented as the absolute vector 211 for ease of description. However, this is only an example and the reliability vector is not limited thereto. For example, the reliability may be measured in proportion to the absolute magnitude of a vector element. A measuring method in which as the absolute value increases, the reliability increases, and as the absolute value approaches 0, the reliability decreases may be used.

In ECC decoding, the reliability vector may contribute to improve the accuracy of error correction and data reconstruction by quantitatively assigning the reliability to each element of the received data. Accordingly, the reliability vector may be implemented in the form of an absolute value or a real-valued vector.

The syndrome vector may be a vector used for detecting an error occurring in the received code word and estimating a location of the error. For example, when the syndrome vector is a non-zero vector, it may indicate that an error has occurred in the received code word. In addition, a value of the syndrome vector may include information on the location and type of the error and through this, may provide an additional clue to correct the error. The syndrome vector may be mainly represented in the form of binary. However, the provided embodiment is not limited thereto and other representations may be allowed.

The ECC decoder 200 may obtain an absolute value (magnitude) and a syndrome value (s(y)) of the received word from the initial embedding layer 210. A binary vector y_{b} may be obtained by mapping a positive number as 0 and a negative number as 1. The syndrome value of the received word may be obtained by binary multiplication of y_{b} and the PCM, in other words, s(y)=Hy_{b}. The absolute value vector |y| 211 of the received word generated from the initial embedding layer 210 may be an n-dimensional absolute value vector 211, and in this case, the syndrome vector s(y) 212 of the received word may be n−k dimensions. In other words, the syndrome vector 212 of the received word may be n−k dimensions because a result of n−k is output when the PCM H is multiplied by the absolute value n of the received word.

The absolute value vector 211 of the received word and the syndrome vector 212 of the received word may be individually projected to a d-dimensional embedding vector. An embedding vector d may be multiplied by the absolute value vector 211 and the syndrome vector 212 element-wise (e.g., n×d, (n−k)×d). The two embedding vectors may be processed as separate input vectors in the decoder layer 220 and unique informational characteristics of the two embedding vectors may be effectively used.

In operation 130, the ECC decoder 200 may update at least one of the reliability vector of the received word and the syndrome vector 212 of the received word at least once based on a plurality of cross-attentions based on the reliability vector and the syndrome vector. The ECC decoder 200 may separately process the absolute value |y| and the syndrome value s(y) of the received word to effectively use the unique informational characteristics thereof. For this, the reliability vector and the syndrome vector 212 may be iteratively updated using the masked cross-attention.

At least one of the plurality of cross-attentions may include the masked cross-attention. The masked cross-attention may update at least one of the reliability vector and the syndrome vector using a mask matrix.

The mask matrix may include a PCM indicating a relationship between an element (or bit) of the received word and a parity check constraint. The PCM and a transpose matrix of the PCM may be used for cross reference update between the reliability vector and the syndrome vector 212.

Referring to FIG. 2, the ECC decoder 200 may include a first cross-attention 221 for updating a reliability vector (e.g., the absolute value vector 211) of a received word or a second cross-attention 222 for updating the syndrome vector 212 of the received word. A feed forward neural network (FFNN) may follow each cross-attention.

In the decoder layer 220 of the ECC decoder 200 according to an embodiment, the first cross-attention 221 may update the reliability vector of the received word by projecting (or encoding) the reliability vector of the received word to a query and projecting the syndrome vector 212 of the received word to a key and a value. The first cross-attention 221 may use a first mask matrix based on the PCM. In this case, the transpose matrix H^{T} of the PCM may be used as the first mask matrix.

The query, key, and value may be main components used in an attention mechanism of a transformer model. The query may be a portion of an input currently being processed and may be used as a reference point for evaluating relationships with all other portions. For example, when processing a word in a sentence, the word may be set to be a query to evaluate relationships with other words in the sentence. The key may be a target to be evaluated by the query. Each portion of the input data may be represented as one key and relevance may be evaluated by comparing the key with the query. The value may include real data related to the key and after the relationship between the key and the query is calculated, the value may contribute to generating a final output by assigning a weight to each value according to the intensity of the relationship. In other words, when a value related to a specific key is evaluated that the value is more relevant to the query, the value may have a greater influence on the final output.

Matrices W_{Q}, W_{K}, and W_{V} for respectively generating the query, key, and value may be learnable matrices and may be d×d matrices. Projecting to a query may be a value obtained by multiplying W_{Q} by a target vector (e.g., the absolute value vector 211 of the received word). Similarly, projecting to a key and a value may be values obtained by multiplying W_{K} and W_{V} by the target vector (e.g., the syndrome vector 212 of the received word), respectively. In this case, W_{Q}, W_{K}, and W_{V} may be parameters shared with cross-attentions of the ECC decoder 200.

In the decoder layer 220 of the ECC decoder 200 according to an embodiment, the second cross-attention 222 may update the syndrome vector 212 of the received word by projecting the syndrome vector 212 of the received word to a query and projecting the reliability vector of the received word to a key and a value. The second cross-attention 222 may use a second mask matrix based on the PCM. In this case, the PCM H may be used as the second mask matrix.

When the update of the reliability vector (e.g., the absolute value vector 211) of the received word in the first cross-attention 221 is performed prior to the update of the syndrome vector 212 of the received word in the second cross-attention 222, the updated reliability vector (e.g., an absolute value vector 221-1) of the received word in the first cross-attention 221 may be used as an input to the second cross-attention 222 by projecting the updated reliability vector to a key and a value.

More specifically, the first cross-attention 221 may generate an attention map of which an absolute value is n×(n−k) wherein a row represents the reliability (or an absolute value) and a column represents the syndrome to represent the “reliability (or the absolute value)—syndrome” relationship. In response to the relationship, the first cross-attention 221 may apply the transpose matrix H^{T} of the PCM to the first mask matrix. Because a n-th row of H^{T} may be connected to |y| in correspondence with a location of an n bit (or element) and an n−k-th row may be connected to s(y) in correspondence with a parity check equation. An output of the first cross-attention 221 may be the updated reliability vector (or the absolute value vector 221-1) of the received word.

Thereafter, the updated reliability vector (e.g., the absolute value vector 221-1) of the received word may be used to update the syndrome vector 212 of the received word in the second cross-attention 222. In the second cross-attention 222, the syndrome vector 212 of the received word may be updated by projecting the syndrome vector 212 of the received word to a query and projecting the updated reliability vector of the received word to a key and a value. The second cross-attention 222 may generate an attention map of which the reliability (or the absolute value) is (n−k)×n and may use the PCM H as the second mask matrix. Because an n−k row of H may be connected to s(y) in correspondence with the parity check equation and an n-th column may be connected to |y| in correspondence with a location of an n-th bit (or element) of the code word. An output of the second cross-attention 222 may be the updated syndrome vector 212 of the received word.

However, the embodiment of FIG. 2 describes that the first cross-attention 221 is performed prior to the second cross-attention 222, and thereby, the absolute value vector 211, which is the output of the first cross-attention 221, of the received word is updated first and the updated absolute value vector 221-1 of the received word is used to update the syndrome vector 212 of the received word in the second cross-attention 222. However, unlike the provided embodiment and FIG. 2, the operation order of the first cross-attention 221 and the second cross-attention 222 may be changed so that the second cross-attention 222 is performed first.

When the update of the syndrome vector 212 of the received word in the second cross-attention 222 is performed prior to the update of the reliability vector (e.g., the absolute value vector 211) of the received word in the first cross-attention 221, an updated syndrome vector 222-1 of the received word in the second cross-attention 222 may be used as an input to the first cross-attention 221 by projecting the updated syndrome vector 222-1 to a key and a value.

More specifically, the syndrome vector 212 of the received word may be updated by projecting the syndrome vector 212 of the received word to a query in the second cross-attention 222 and projecting the reliability vector (or the absolute value vector 211) of the received word to a key and a value. The second cross-attention 222 may generate an attention map of which an absolute value is (n−k)×n and may use the PCM H as the second mask matrix. Because an n−k row of H may be connected to s(y) in correspondence with the parity check equation and an n-th column may be connected to |y| in correspondence with a location of an n-th bit. An output of the second cross-attention 222 may be the updated syndrome vector 212 of the received word.

Thereafter, the reliability vector of the received word may be updated by projecting the reliability vector of the received word to a query in the first cross-attention 221 and projecting the updated syndrome vector 212 of the received word to a key and a value.

The first cross-attention 221 may generate an attention map of which the reliability (or an absolute value) is n×(n−k) wherein a row represents the reliability and a column represents the syndrome to represent the “reliability-syndrome” relationship. In response to the relationship, the first cross-attention 221 may apply the transpose matrix H^{T} of the PCM to the first mask matrix. Because a n-th row of H^{T} may be connected to |y| in correspondence with a location of an n bit (or element) and an n−k-th row may be connected to s(y) in correspondence with a parity check equation. An output of the first cross-attention 221 may be the updated absolute value vector 221-1 of the received word.

The first cross-attention 221 may generate an attention map of which the reliability (or an absolute value) is n×(n−k) wherein a row represents the reliability and a column represents the syndrome to represent the “reliability-syndrome” relationship. In response to the relationship, the first cross-attention 221 may apply the transpose matrix H^{T} of the PCM to a mask matrix. Because a n-th row of H^{T} may be connected to |y| in correspondence with a location of an n bit and an n−k-th row may be connected to s(y) in correspondence with a parity check equation. An output of the first cross-attention 221 may be the updated reliability vector (or the absolute value vector 221-1) of the received word.

The ECC decoder 200 according to an embodiment may iteratively update the reliability vector (e.g., the absolute value vector 211) of the received word and the syndrome vector 212 of the received word. The ECC decoder 200 may iteratively update the reliability vector and the syndrome vector 212 to accurately identify multiplicative noise. The number of iterative updates may vary depending on the reliability of a message, transmission code of a code word, etc.

In operation 140, the ECC decoder 200 may output an estimate of the transmitted code word based on an update result. In the output layer 230 of the ECC decoder 200, an updated final reliability vector (e.g., a final absolute value vector 231) of the received word and an updated final syndrome vector 232 of the received word may be concatenated to a single input vector (2n−k) and the single input vector may pass through a normalization layer Norm and two fully connected (FC) layers. A first fully connected layer 233 may reduce ((2n−k)×d)-dimensional embedding to ((2n−k)×1) dimensions and a second fully connected layer 234 may reduce ((2n−k)×1)-dimensional embedding to (n×1), and thereby, a final estimate of multiplicative noise of an absolute value n may be output as an output vector.

More specifically, when ƒ(y)=2, is an estimate vector of the multiplicative noise estimated by the ECC decoder 200, an estimate of the transmitted code word may be obtained as \hat{x}=bin(sign(yƒ(y))). In other words, in a received word y=xₛ+z=xₛ×\tilde{z}ₛ, multiplicative noise [symbol] may be learned based on the PCM used as a mask matrix. The ECC decoder 200 (e.g., the CrossMPT) may aim to estimate the multiplicative noise. Accordingly, ƒ(y)=\hat{z}ₛ may be satisfied and an estimate of the transmitted code word, which is a transmitted original code word, may be \hat{x}=bin(sign(yƒ(y))). When the multiplicative noise is correctly estimated, sign(\tilde{z}ₛ)=sign(\hat{z}ₛ) may be satisfied and sign(\tilde{z}ₛ\hat{z}ₛ)=1 may be satisfied. In this case, \hat{x} may be obtained by Equation 1 below.

$$\hat{x} = bin ( sign ( yf ( y ) ) ) = bin ( sign ( {x}_{s} {\tilde{z}}_{s} {\hat{z}}_{s} ) ) = bin ( sign ( {x}_{s} ) ) = x \qquad [ Equation 1 ]$$

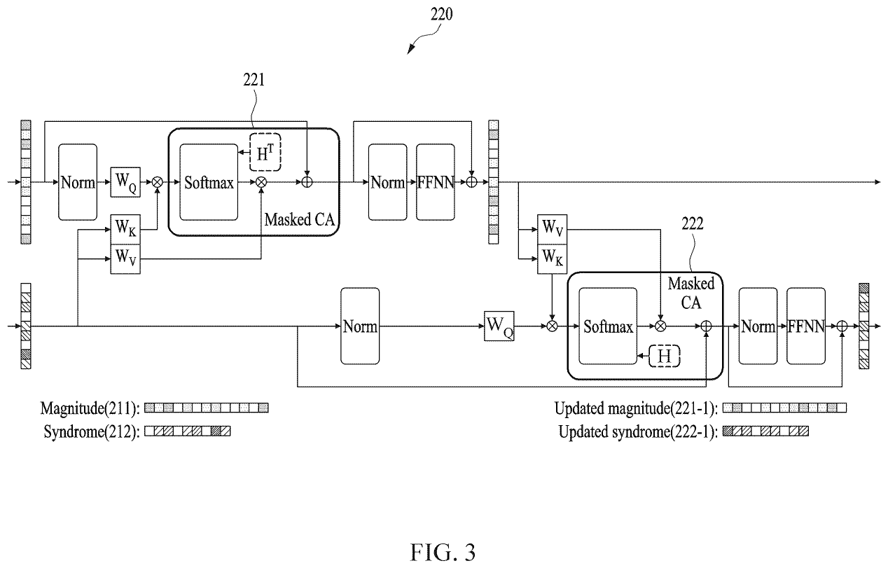

FIGS. 2 and 3 are diagrams schematically illustrating operations of an ECC decoder including a cross-attention message-passing transformer (CrossMPT) according to an embodiment.

The description provided with reference to FIG. 1 may apply to FIGS. 2 and 3, and any repeated description related thereto may be omitted.

As illustrated in FIGS. 2 and 3, one or more blocks and a combination of the blocks may be implemented by a special-purpose hardware-based computer that performs a predetermined function or a combination of computer instructions and special-purpose hardware.

Referring to FIGS. 2 and 3, the ECC decoder 200 according to an embodiment may generate a reliability vector |y| (e.g., the absolute value vector 211) and the syndrome vector s(y) 212 of a received word y in the initial embedding layer 210. Instead of concatenating |y| and s(y), each vector may be regarded as a separate input in the CrossMPT of the ECC decoder 200. All elements of the n-dimensional absolute value vector |y| 211 and the (n−k)-dimensional syndrome vector s(y) 212 may be individually projected to a d-dimensional embedding vector. The two embedding vectors may be processed as separate input vectors in following N decoder layers 220. The decoder layer 220 may include cross-attentions and may include a normalization layer and an FFNN.

In the first cross-attention 221, |y| may be projected to a query, and s(y) may be projected to a key and a value. The first cross-attention 221 may generate an attention map of an absolute value n×(n−k) representing the “absolute value-syndrome” relationship. Accordingly, the n-th row of H^{T} may relate to an n-bit location and the (n−k)-th column of H^{T} may correspond to a parity check equation, and thus, a transpose matrix of the PCM H^{T} may be used as a mask matrix. An output vector may be the absolute value vector 221-1 that is newly updated using the syndrome vector 212.

Subsequently, the updated |y| may be used to update s(y) in the following second cross-attention 222. In the second cross-attention 222, s(y) may be projected to a query and the updated |y| may be updated to a key and a value. The second cross-attention 222 may use the PCM H as a mask matrix. An output vector of the second cross-attention 222 may be the updated syndrome vector 222-1 and the updated syndrome vector 222-1 may be used to refine the absolute value vector 211. The process of the decoder layer 220 may be iteratively performed to more precisely update the absolute value vector 211 and the syndrome vector 212.

After the final update is completed, the final updated absolute value vector 231 and the final updated syndrome vector 232, which are the output vectors of the decoder layer 220, may be concatenated and may pass through the normalization layer and two FC layers. The first FC layer 233 may reduce (2n−k)×d-dimensional embedding to a one-dimensional 2n−k vector and the second FC layer 234 may further reduce the dimension from 2n−k to n. A final output of the ECC decoder 200 may be an estimate for \tilde{z}ₛ.

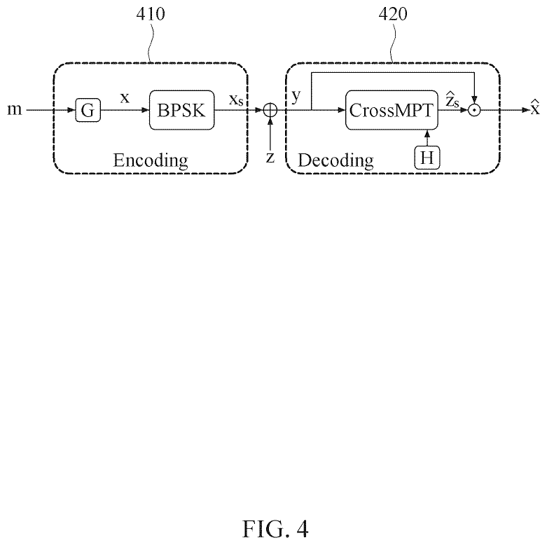

FIG. 4 schematically illustrates a digital communication system applied with CrossMPT according to an embodiment.

The description provided with reference to FIGS. 1 to 3 may apply to FIG. 4, and any repeated description related thereto may be omitted.

Referring to FIG. 4, a code word encoder 410 according to an embodiment may convert a transmitted code word into a received word.

It may be assumed that C defined by a generator matrix G of an absolute value k×n and a PCM H of an absolute value (n−k)×n is referred to as linear block code and C satisfies GH^{T}=0 for {0, 1} in modulo 2 addition. The modulo 2 addition may be an XOR (exclusive or) operation that returns 0 when adding two bits and the two bits are the same and returns 1 when the two bits are different.

A transmitted code word x∈C⊂{0, 1}ⁿ may multiply and project the generator matrix G by a message m (in other words, x=mG). When xₛ is a BPSK modulated version of x (e.g., in the case of binary phase shift modulation, when x=0, xₛ=+1 is satisfied, and when x=1, xₛ=−1 is satisfied), y may be an output of a noise channel for the input xₛ. In this case, when it is assumed that the channel is an AWGN channel, a channel output may be defined by y=xₛ+z where the AWGN may be represented as z˜N(0,σ²).

An ECC decoder 420 (e.g., the ECC decoder 200) according to an embodiment may estimate a transmitted code word from a received word. The ECC decoder 420 (ƒ: [symbol] ⁿ→ [symbol] ⁿ) may reconstruct a transmitted code word x, which is an original code word that is originally transmitted as an error is modified in the received word. When a received word y is received, the ECC decoder 420 may firstly identify a syndrome s(y)=Hy_{b} to determine whether a received signal is corrupted and in this case, y_{b}=bin(sign(y)) may be a demodulated signal of y. In this case, sign(a) may denote +1 if a≥0 is satisfied, and if not, −1, and bin(−1)=1, bin(+1)=0. When s(y) is a non-zero vector, it may be detected that y is corrupted during the transmission and the decoder may begin an error correcting process.

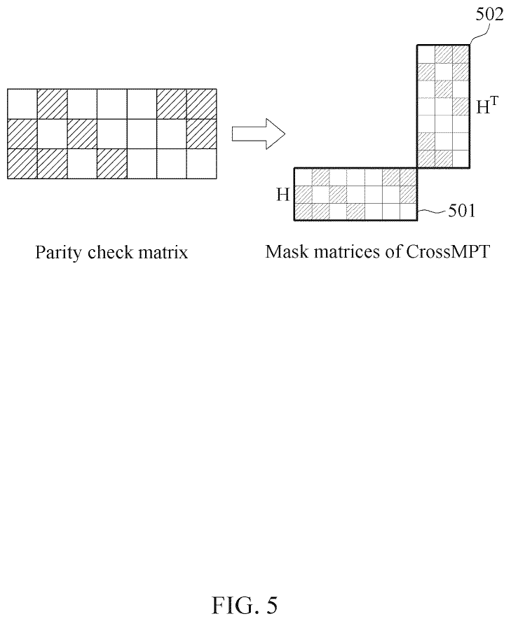

FIG. 5 is a schematic diagram illustrating a parity check matrix according to an embodiment.

The description provided with reference to FIGS. 1 to 4 may apply to FIG. 5, and any repeated description related thereto may be omitted.

The ECC decoder 200 may use a masked cross-attention to train a transformer architecture that uses a reliability vector (e.g., an absolute value vector) and a syndrome vector of y, which are input embedding vectors, as inputs. The ECC decoder 200 may encapsulate information about the relationship between the bits (or elements) of a code word, as the mask matrix of the cross-attention is implemented based on a parity check matrix (PCM).

Referring to FIG. 2, the PCM, which is a mask matrix of the CrossMPT of the ECC decoder 200 may include a relationship between an absolute value and a syndrome. The CrossMPT may adopt a masked cross-attention because it only uses a mask matrix indicating the relationship between the absolute value and the syndrome. As described above, a PCM H 501 and a transpose matrix H^{T} of the PCM may indicate a parity transpose matrix H 501 (a syndrome-absolute value relationship) and a transpose matrix H^{T} 502 thereof (an absolute value-syndrome relationship), which are mask matrices of two masked cross-attentions in the CrossMPT.

Referring to the PCM H 501, in the PCM H 501, a column may indicate an element (or bit) of the code word and a row may indicate a parity check equation. In other words, the PCM may indicate a relationship between the element (or bit) of the code word and the parity check equation. Accordingly, a white portion may be 1 and a black portion filled with color may be 0. For example, since the first row indicates the first parity check equation in the PCM H of FIG. 5, the first parity check equation may be related to bits of the first, third, fourth, and fifth code words in which 1 is written.

Similarly, referring to the parity check transpose matrix H^{T} 502, in the parity check transpose matrix H^{T} 502, a row may indicate a bit and a column may indicate a parity check equation. In other words, the parity check transpose matrix H^{T} 502 may indicate a relationship between the parity check equation and the bit. Accordingly, a white portion may be 1 and a black portion filled with color may be 0. For example, since the first row indicates the first bit in the parity check transpose matrix H^{T} 502 of FIG. 5, the first bit may be related to the first parity check equation in which 1 is written.

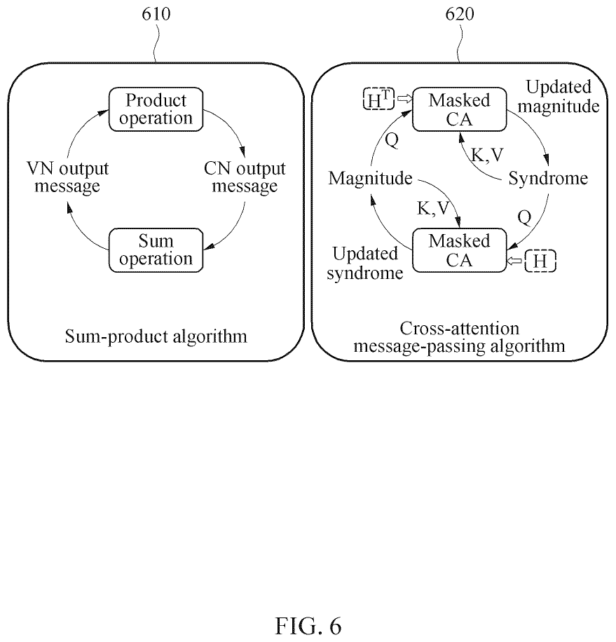

FIG. 6 schematically illustrates a conceptual example of a message-passing algorithm according to an embodiment.

The description provided with reference to FIGS. 1 to 5 may apply to FIG. 6, and any repeated description related thereto may be omitted.

Referring to FIG. 6, as a representative example of a message-passing algorithm, a sum-product algorithm 610 and a cross-attention message-passing algorithm 620 (e.g., the CrossMPT) described above may be provided. In the sum-product algorithm 610, VN output and CN output messages may be iteratively updated using a sum-product operation. Similar to the sum-product algorithm 610, the absolute value vector 211 and the syndrome vector 212 may be iteratively updated using a masked cross-attention block of the cross-attention message-passing algorithm 620. H and H^{T} may be used for this mask matrix of the cross-attention block and Q, K, and V may respectively denote a query, a key, and a value of the cross-attention mechanism.

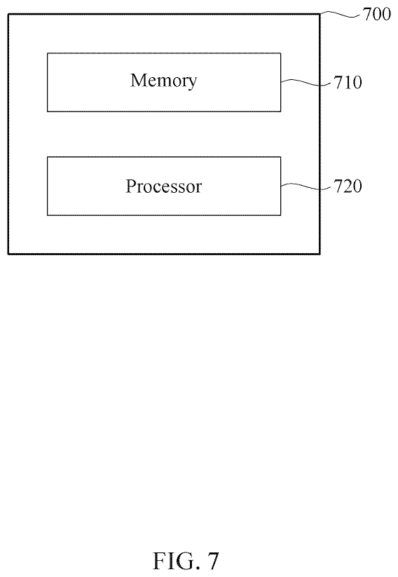

FIG. 7 is a diagram illustrating a block diagram of an electronic device according to an embodiment.

In FIG. 7, one or more blocks and a combination thereof may be implemented by a special-purpose hardware-based computer that performs a predetermined function, or a combination of computer instructions and special-purpose hardware. The description provided with reference to FIGS. 1 to 3 may also apply to FIG. 4. For example, an electronic device 700 according to an embodiment may include the ECC decoder 200.

As shown in FIG. 7, the electronic device 700 may include a memory 710 and a processor 720. The electronic device 700 may further include a communication module, and the communication module may include a transmitter and a receiver.

The electronic device 700 according to an embodiment may include the memory 710 and the processor 720 connected to the memory 710 via a system bus or another appropriate circuit.

The electronic device 700 may store program code in the memory 710. The memory 710, according to an embodiment, may include a local memory or at least one physical memory device, such as at least one bulk storage device. Here, the local memory may include a random access memory (RAM) or other volatile memory devices generally used during the actual execution of the program code. The bulk storage device may be implemented as a hard disk drive (HDD), a solid state drive (SSD), or other non-volatile memory devices.

In response to the executable program code stored in the memory 710 being executed by the electronic device 700, the processor 720 may perform various operations disclosed herein. For example, the memory 710 may store the program code such that the processor 720 may perform at least one operation described with reference to FIGS. 1 to 6.

Depending on the type of apparatus to be implemented, the electronic device 700 may include components less than the number of the illustrated components or may include additional components that are not illustrated in FIG. 7. Also, at least one component may be included in another component and may constitute a portion of the other component.

The processor 720, according to an embodiment, is a hardware configuration that performs overall control functions for controlling operations of the electronic device 700. For example, the processor 720 may generally control the electronic device 700 by executing programs stored in the memory 710 in the electronic device 700. The processor 720 may be implemented as a central processing unit (CPU), a graphics processing unit (GPU), an application processor (AP), a neural processing unit (NPU), and the like, which are included in the electronic device 700, but examples are not limited thereto.

The processor 720 may obtain a received word generated based on a transmitted code word, may obtain a reliability vector of the received word and a syndrome vector of the received word, may update at least one of the reliability vector of the received word and the syndrome vector of the received word at least once based on a plurality of cross-attentions based on the reliability vector and the syndrome vector, and may output an estimate of the transmitted code word based on an update result.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a DSP, a microcomputer, an FPGA, a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and multiple types of processing elements. For example, the processing device may include a plurality of processors, or a single processor and a single controller. In addition, different processing configurations are possible, such as parallel processors.

The software may include a computer program, a piece of code, an instruction, or some combination thereof, to independently or uniformly instruct or configure the processing device to operate as desired. Software and data may be embodied permanently or temporarily in any type of machine, component, physical or pseudo equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher-level code that may be executed by the computer using an interpreter.

The above-described devices may be configured to act as one or more software modules in order to perform the operations of the above-described examples, or vice versa.

As described above, although the embodiments have been described with reference to the limited drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

What is claimed is:

1. A method of decoding error correcting code (ECC), the method comprising:
obtaining a received word generated based on a transmitted code word;
obtaining a reliability vector of the received word and a syndrome vector of the received word;
updating at least one of the reliability vector of the received word and the syndrome vector of the received word at least once based on a plurality of cross-attentions based on the reliability vector and the syndrome vector; and
outputting an estimate of the transmitted code word based on a result of the update.

2. The method of claim 1, wherein at least one of the plurality of cross-attentions comprises a masked cross-attention, and
the masked cross-attention updates at least one of the reliability vector and the syndrome vector using a mask matrix.

3. The method of claim 2, wherein the mask matrix comprises a parity check matrix indicating a relationship between an element of the received word and a parity check constraint, and
the parity check matrix and a transpose matrix of the parity check matrix are used for a cross-reference update between the reliability vector and the syndrome vector.

4. The method of claim 1, wherein the cross-attention comprises a first cross-attention configured to update the reliability vector of the received word and a second cross-attention configured to update the syndrome vector of the received word.

5. The method of claim 4, wherein the updating at least once comprises:
updating the reliability vector of the received word by projecting the reliability vector of the received word to a query and projecting the syndrome vector of the received word to a key and a value.

6. The method of claim 5, wherein the updating of the reliability vector of the received word comprises:
using a first mask matrix based on the parity check matrix.

7. The method of claim 4, wherein the updating at least once comprises:
updating the syndrome vector of the received word by projecting the syndrome vector of the received word to a query and projecting the reliability vector of the received word to a key and a value.

8. The method of claim 7, wherein the updating of the syndrome vector of the received word comprises:
using a second mask matrix based on the parity check matrix.

9. The method of claim 4, wherein the updating at least once comprises:
when the update of the reliability vector of the received word in the first cross-attention is performed prior to the update of the syndrome vector of the received word in the second cross-attention, projecting an updated reliability vector of the received word in the first cross-attention to a key and a value and using the projected key and value as an input of the second cross-attention.

10. The method of claim 4, wherein the updating at least once comprises:
when the update of the syndrome vector of the received word in the second cross-attention is performed prior to the update of the reliability vector of the received word in the first cross-attention, projecting an updated syndrome vector of the received word in the second cross-attention to a key and a value and using the projected key and value as an input of the first cross-attention.

11. The method of claim 1, wherein the received word is converted by applying binary phase shift keying (BPSK) and additive white Gaussian noise (AWGN) to the transmitted code word.

12. A non-transitory computer-readable storage medium storing instructions that, when executed by a processor, cause the processor to perform the method of claim 1.

13. An electronic device comprising:
a memory configured to store instructions; and
one or more processors,
wherein the instructions, when performed by the one or more processors, cause the electronic device to:
obtain a received word generated based on a transmitted code word,
obtain a reliability vector of the received word and a syndrome vector of the received word,
update at least one of the reliability vector of the received word and the syndrome vector of the received word at least once based on a plurality of cross-attentions based on the reliability vector and the syndrome vector, and
output an estimate of the transmitted code word based on a result of the update.

14. The electronic device of claim 13, wherein at least one of the plurality of cross-attentions comprises a masked cross-attention, and
the masked cross-attention updates at least one of the reliability vector and the syndrome vector using a mask matrix.

15. The electronic device of claim 14, wherein the mask matrix comprises a parity check matrix indicating a relationship between an element of the received word and a parity check constraint, and
the parity check matrix and a transpose matrix of the parity check matrix are used for cross-reference update between the reliability vector and the syndrome vector.

16. The electronic device of claim 13, wherein the cross-attention comprises a first cross-attention configured to update the reliability vector of the received word and a second cross-attention configured to update the syndrome vector of the received word.

17. The electronic device of claim 16, wherein the instructions, when performed by the one or more processors, cause the electronic device to:
update the reliability vector of the received word by projecting the reliability vector of the received word to a query and projecting the syndrome vector of the received word to a key and a value.

18. The electronic device of claim 16, wherein the instructions, when performed by the one or more processors, cause the electronic device to:
update the syndrome vector of the received word by projecting the syndrome vector of the received word to a query and projecting the reliability vector of the received word to a key and a value.

19. An error correcting code (ECC) decoder comprising:
an embedding layer configured to obtain a reliability vector of a received word generated based on a transmitted code word and a syndrome vector of the received word;
a decoder layer configured to update at least one of the reliability vector of the received word and the syndrome vector of the received word at least once and comprising a plurality of cross-attentions; and
an output layer configured to output an estimate of the transmitted code word based on a result of the update.

20. The ECC decoder of claim 19, wherein at least one of the plurality of cross-attentions comprises a masked cross-attention, and
the masked cross-attention updates at least one of the reliability vector and the syndrome vector using a mask matrix.
